(19) United States
(12) Patent Application Publication
(10) Pub. No.: US 2014/0162384 A1
(43) Pub. Date: Jun. 12, 2014

(54) PVD-ALD-CVD hybrid HPC for work function material screening

(71) Applicant: INTERMOLECULAR INC., San Jose, CA (US)

(72) Inventor: Amol Joshi, Sunnyvale, CA (US)

(73) Assignee: Intermolecular Inc., San Jose, CA (US)

(21) Appl. No.: 13/706,648

(22) Filed: Dec. 6, 2012

(51) Int. Cl. H01L 21/66

(52) U.S. Cl. CPC H01L 22/10; H01L 22/14
USPC 438/17; 438/14

(57) ABSTRACT

A substrate is provided wherein the substrate includes a number of site-isolated regions (SIRs). At least one material is deposited using PVD on a sub-set of the SIRs. At least one of the material or the process conditions are varied in a combinatorial manner across the sub-set of SIRs. Next, at least one material is deposited using ALD on a sub-set of the SIRs. At least one of the material or the process conditions are varied in a combinatorial manner across the sub-set of SIRs. Next, a material is deposited across the entire substrate using CVD. Each device within each of the SIRs is evaluated for at least one of an electric property or a material property.

### FIELD OF THE INVENTION

The present invention relates generally to methods for the deposition of materials on site isolated regions of a substrate in a combinatorial manner. The apparatus is operable to deposit materials using physical vapor deposition (PVD), chemical vapor deposition (CVD), or atomic layer deposition (ALD) technologies. Additionally, the apparatus is compatible with the plasma enhanced versions of these technologies (i.e. PECVD and PEALD).

### BACKGROUND OF THE INVENTION

The manufacture of semiconductor devices, TFPV modules, optoelectronic devices, etc. entails the integration and sequencing of many unit processing steps. As an example, device manufacturing typically includes a series of processing steps such as cleaning, surface preparation, deposition, patterning, etching, thermal annealing, and other related unit processing steps. The precise sequencing and integration of the unit processing steps enables the formation of functional devices meeting desired performance metrics such as efficiency, power production, and reliability.

As part of the discovery, optimization and qualification of each unit process, it is desirable to be able to i) test different materials, ii) test different processing conditions within each unit process module, iii) test different sequencing and integration of processing modules within an integrated processing tool, iv) test different sequencing of processing tools in executing different process sequence integration flows, and combinations thereof in the manufacture of devices such as integrated circuits. In particular, there is a need to be able to test i) more than one material, ii) more than one processing condition, iii) more than one sequence of processing conditions, iv) more than one process sequence integration flow, and combinations thereof, collectively known as “combinatorial process sequence integration”, on a single monolithic substrate without the need of consuming the equivalent number of monolithic substrates per material(s), processing condition(s), sequence(s) of processing conditions, sequence(s) of processes, and combinations thereof. This can greatly improve both the speed and reduce the costs associated with the discovery, implementation, optimization, and qualification of material(s), process(es), and process integration sequence(s) required for manufacturing.

Systems and methods for High Productivity Combinatorial (HPC) processing are described in U.S. Pat. No. 7,544,574 filed on Feb. 10, 2006, U.S. Pat. No. 7,824,935 filed on Jul. 2, 2008, U.S. Pat. No. 7,871,928 filed on May 4, 2009, U.S. Pat. No. 7,902,063 filed on Feb. 10, 2006, and U.S. Pat. No. 7,947,531 filed on Aug. 28, 2009 which are all herein incorporated by reference. Systems and methods for HPC processing are further described in U.S. patent application Ser. No. 11/352,077 filed on Feb. 10, 2006, claiming priority from Oct. 15, 2005, U.S. patent application Ser. No. 11/419,174 filed on May 18, 2006, claiming priority from Oct. 15, 2005, U.S. patent application Ser. No. 11/674,132 filed on Feb. 12, 2007, claiming priority from Oct. 15, 2005, and U.S. patent application Ser. No. 11/674,137 filed on Feb. 12, 2007, claiming priority from Oct. 15, 2005 which are all herein incorporated by reference.

HPC processing techniques have been successfully adapted to wet chemical processing such as etching and cleaning. HPC processing techniques have also been successfully adapted to deposition processes such as physical vapor deposition (PVD), atomic layer deposition (ALD), and chemical vapor deposition (CVD). However, the CVD and ALD adaptations of HPC techniques generally deposit materials on relatively large areas of the substrate. As an example, ALD deposition on a quarter of the substrate is common. However, it is desirable to deposit materials on a substrate using CVD or ALD in a site isolated manner wherein the size of the region is very small relative to the substrate. Therefore, there is a need to develop methods that enable the deposition of materials using CVD, PECVD, ALD, or PEALD on small spots in a site isolated, combinatorial manner to form multilayer film stacks.

### SUMMARY OF THE DISCLOSURE

The following summary of the invention is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

A substrate is provided wherein the substrate includes a number of site-isolated regions (SIRs). At least one material is deposited using PVD on a sub-set of the SIRs. At least one of the material or the process conditions are varied in a combinatorial manner across the sub-set of SIRs. Next, at least one material is deposited using ALD on a sub-set of the SIRs. At least one of the material or the process conditions are varied in a combinatorial manner across the sub-set of SIRs. Next, a material is deposited across the entire substrate using CVD. Each device within each of the SIRs is evaluated for at least one of an electric property or a material property.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 is a schematic diagram for implementing combinatorial processing and evaluation.

FIG. 2 is a schematic diagram for illustrating various process sequences using combinatorial processing and evaluation.

FIG. 3 is a simplified schematic diagram illustrating an integrated high productivity combinatorial (HPC) system in accordance with some embodiments.

FIG. 4 is a simplified schematic diagram illustrating a sputter processing chamber configured to perform combinatorial processing and full substrate processing in accordance with some embodiments.

FIG. 5A illustrates an example of a large area ALD or CVD showerhead used for combinatorial processing.

FIG. 5B illustrates a bottom view of two examples of a small spot showerhead apparatus in accordance with some embodiments.

FIG. 6 illustrates one example of a pattern of site isolated regions that can be processed using a small spot showerhead apparatus in accordance with some embodiments.

FIGS. 7A-7C illustrate a top view of site-isolated regions and film stacks formed by a PVD-ALD-CVD sequence in accordance with some embodiments.

FIG. 8 illustrates a side view of site-isolated regions and film stacks formed by a PVD-ALD-CVD sequence in accordance with some embodiments.

FIG. 9 illustrates a flow chart describing a method for fabricating a capacitor stack in accordance with some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

The performance of several semiconductor devices is influenced by the work function of the materials selected for use as the electrodes of the device. Examples of these semiconductor devices include capacitors and transistors. The electrode materials for these devices include metals, metal alloys, conductive metal nitrides, conductive metal silicides, conductive metal oxides, or conductive metal carbides. The work function of the materials will vary with material composition and with variations in deposition technique and deposition process conditions. Therefore, the work function must be measured and evaluated as a function of many variables. Due to wafer-to-wafer variation, it is desirable to evaluate the influence of all of the variables on a single, or small number, of wafers. In some embodiments, methods are provided wherein the deposition technique and deposition process condition variables are varied in a combinatorial manner on a single, or small number, of wafers.

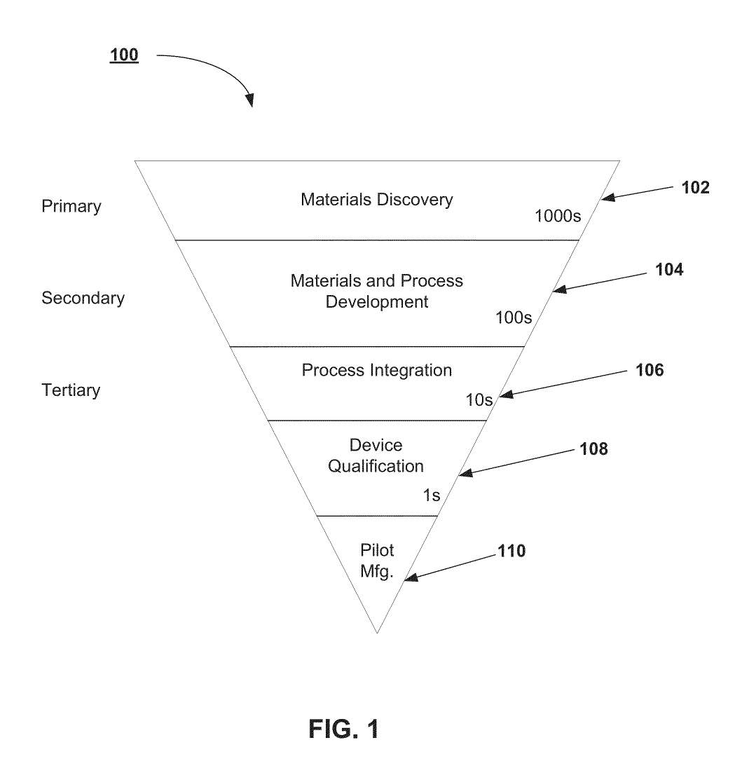

FIG. 1 illustrates a schematic diagram, 100, for implementing combinatorial processing and evaluation using primary, secondary, and tertiary screening. The schematic diagram, 100, illustrates that the relative number of combinatorial processes run with a group of substrates decreases as certain materials and/or processes are selected. Generally, combinatorial processing includes performing a large number of processes during a primary screen, selecting promising candidates from those processes, performing the selected processing during a secondary screen, selecting promising candidates from the secondary screen for a tertiary screen, and so on. In addition, feedback from later stages to earlier stages can be used to refine the success criteria and provide better screening results.

For example, thousands of materials are evaluated during a materials discovery stage, 102. Materials discovery stage, 102, is also known as a primary screening stage performed using primary screening techniques. Primary screening techniques may include dividing substrates into coupons and depositing materials using varied processes. The materials are then evaluated, and promising candidates are advanced to the secondary screen, or materials and process development stage, 104. Evaluation of the materials is performed using metrology tools such as electronic testers and imaging tools (i.e., microscopes).

The materials and process development stage, 104, may evaluate hundreds of materials (i.e., a magnitude smaller than the primary stage) and may focus on the processes used to deposit or develop those materials. Promising materials and processes are again selected, and advanced to the tertiary screen or process integration stage, 106, where tens of materials and/or processes and combinations are evaluated. The tertiary screen or process integration stage, 106, may focus on integrating the selected processes and materials with other processes and materials.

The most promising materials and processes from the tertiary screen are advanced to device qualification, 108. In device qualification, the materials and processes selected are evaluated for high volume manufacturing, which normally is conducted on full substrates within production tools, but need not be conducted in such a manner. The results are evaluated to determine the efficacy of the selected materials and processes. If successful, the use of the screened materials and processes can proceed to pilot manufacturing, 110.

The schematic diagram, 100, is an example of various techniques that may be used to evaluate and select materials and processes for the development of new materials and processes. The descriptions of primary, secondary, etc. screening and the various stages, 102-110, are arbitrary and the stages may overlap, occur out of sequence, be described and be performed in many other ways.

This application benefits from High Productivity Combinatorial (HPC) techniques described in U.S. patent application Ser. No. 11/674,137 filed on Feb. 12, 2007 which is hereby incorporated for reference in its entirety. Portions of the '137 application have been reproduced below to enhance the understanding of the present invention. The embodiments described herein enable the application of combinatorial techniques to process sequence integration in order to arrive at a globally optimal sequence of semiconductor devices, TFPV modules, optoelectronic devices, etc. manufacturing operations by considering interaction effects between the unit manufacturing operations, the process conditions used to effect such unit manufacturing operations, hardware details used during the processing, as well as materials characteristics of components utilized within the unit manufacturing operations. Rather than only considering a series of local optimums, i.e., where the best conditions and materials for each manufacturing unit operation is considered in isolation, the embodiments described below consider interactions effects introduced due to the multitude of processing operations that are performed and the order in which such multitude of processing operations are performed when fabricating semiconductor devices, TFPV modules, optoelectronic devices, etc. A global optimum sequence order is therefore derived and as part of this derivation, the unit processes, unit process parameters and materials used in the unit process operations of the optimum sequence order are also considered.

The embodiments described further analyze a portion or sub-set of the overall process sequence used to manufacture semiconductor devices, TFPV modules, optoelectronic devices, etc. Once the subset of the process sequence is identified for analysis, combinatorial process sequence integration testing is performed to optimize the materials, unit processes, hardware details, and process sequence used to build that portion of the device or structure. During the processing of some embodiments described herein, structures are formed on the processed substrate that are equivalent to the structures formed during actual production of the semiconductor devices, TFPV modules, optoelectronic devices, etc. For example, such structures may include, but would not be limited to, contact layers, buffer layers, absorber layers, or any other series of layers or unit processes that create an intermediate structure found on semiconductor devices, TFPV modules, optoelectronic devices, etc. While the combinatorial processing varies certain materials, unit processes, hardware details, or process sequences, the composition or thickness of the layers or structures or the action of the unit process, such as cleaning, surface preparation, deposition, surface treatment, etc. is substantially uniform through each discrete region. Furthermore, while different materials or unit processes may be used for corresponding layers or steps in the formation of a structure in different regions of the substrate during the combinatorial processing, the application of each layer or use of a given unit process is substantially consistent or uniform throughout the different regions in which it is intentionally applied. Thus, the processing is uniform within a region (inter-region uniformity) and between regions (intra-region uniformity), as desired. It should be noted that the process can be varied between regions, for example, where a thickness of a layer is varied or a material may be varied between the regions, etc., as desired by the design of the experiment.

The result is a series of regions on the substrate that contain structures or unit process sequences that have been uniformly applied within that region and, as applicable, across different regions. This process uniformity allows comparison of the properties within and across the different regions such that the variations in test results are due to the varied parameter (e.g., materials, unit processes, unit process parameters, hardware details, or process sequences) and not the lack of process uniformity. In the embodiments described herein, the positions of the discrete regions on the substrate can be defined as needed, but are preferably systematized for ease of tooling and design of experimentation. In addition, the number, variants and location of structures within each region are designed to enable valid statistical analysis of the test results within each region and across regions to be performed.

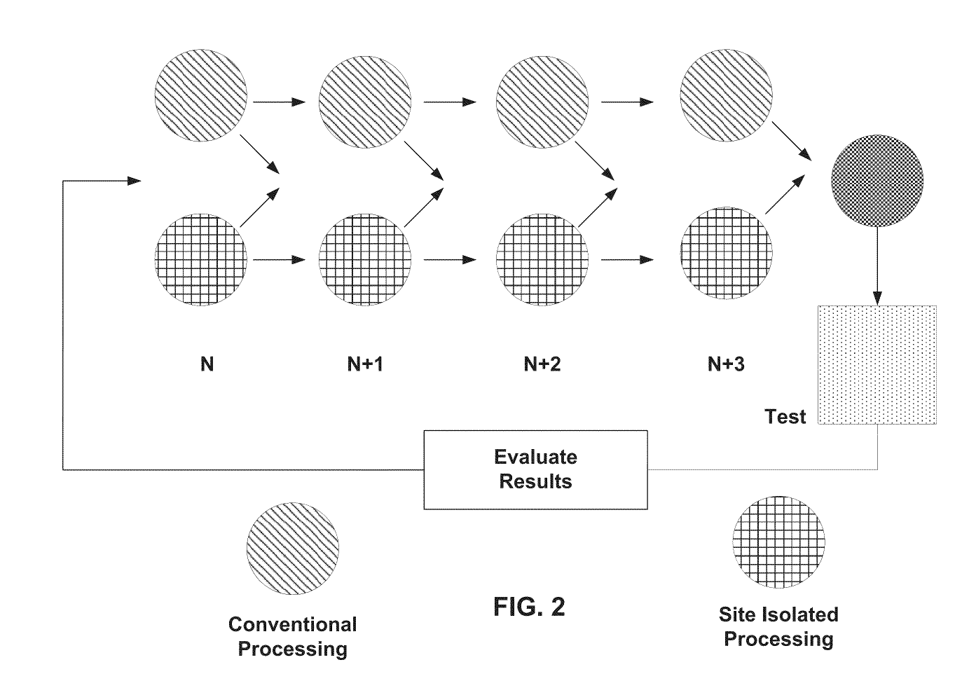

FIG. 2 is a simplified schematic diagram illustrating a general methodology for combinatorial process sequence integration that includes site isolated processing and/or conventional processing in accordance with one embodiment of the invention. In one embodiment, the substrate is initially processed using conventional process N. In one exemplary embodiment, the substrate is then processed using site isolated process N+1. During site isolated processing, an HPC module may be used, such as the HPC module described in U.S. patent application Ser. No. 11/352,077 filed on Feb. 10, 2006. The substrate can then be processed using site isolated process N+2, and thereafter processed using conventional process N+3. Testing is performed and the results are evaluated. The testing can include physical, chemical, acoustic, magnetic, electrical, optical, etc. tests. From this evaluation, a particular process from the various site isolated processes (e.g. from steps N+1 and N+2) may be selected and fixed so that additional combinatorial process sequence integration may be performed using site isolated processing for either process N or N+3. For example, a next process sequence can include processing the substrate using site isolated process N, conventional processing for processes N+1, N+2, and N+3, with testing performed thereafter.

It should be appreciated that various other combinations of conventional and combinatorial processes can be included in the processing sequence with regard to FIG. 2. That is, the combinatorial process sequence integration can be applied to any desired segments and/or portions of an overall process flow. Characterization, including physical, chemical, acoustic, magnetic, electrical, optical, etc. testing, can be performed after each process operation, and/or series of process operations within the process flow as desired. The feedback provided by the testing is used to select certain materials, processes, process conditions, and process sequences and eliminate others. Furthermore, the above flows can be applied to entire monolithic substrates, or portions of monolithic substrates such as coupons.

Under combinatorial processing operations the processing conditions at different regions can be controlled independently. Consequently, process material amounts, reactant species, processing temperatures, processing times, processing pressures, processing flow rates, processing powers, processing reagent compositions, the rates at which the reactions are quenched, deposition order of process materials, process sequence steps, hardware details, etc., can be varied from region to region on the substrate. Thus, for example, when exploring materials, a processing material delivered to a first and second region can be the same or different. If the processing material delivered to the first region is the same as the processing material delivered to the second region, this processing material can be offered to the first and second regions on the substrate at different concentrations. In addition, the material can be deposited under different processing parameters. Parameters which can be varied include, but are not limited to, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, hardware details of the gas distribution assembly, etc. It should be appreciated that these process parameters are exemplary and not meant to be an exhaustive list as other process parameters commonly used in semiconductor device, TFPV module, optoelectronic device, etc. manufacturing may be varied.

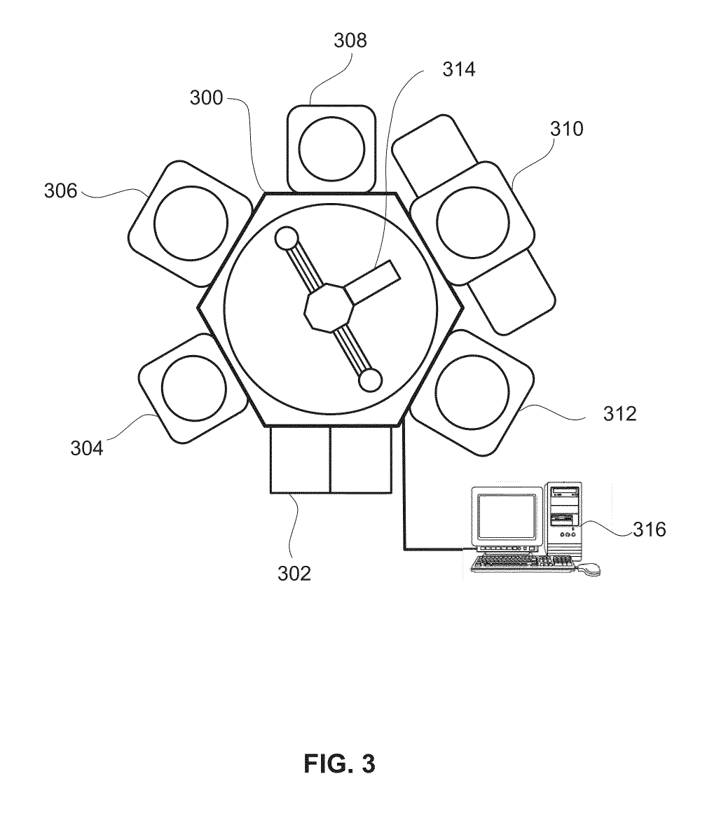

FIG. 3 is a simplified schematic diagram illustrating an integrated high productivity combinatorial (HPC) system in accordance with some embodiments of the invention. HPC system includes a frame 300 supporting a plurality of processing modules. It should be appreciated that frame 300 may be a unitary frame in accordance with some embodiments. In some embodiments, the environment within frame 300 is controlled. Load lock/factory interface 302 provides access into the plurality of modules of the HPC system. Robot 314 provides for the movement of substrates (and masks) between the modules and for the movement into and out of the load lock 302. Modules 304-312 may be any set of modules and preferably include one or more combinatorial modules. For example, module 304 may be an orientation/degassing module, module 306 may be a clean module, either plasma or non-plasma based, modules 308 and/or 310 may be combinatorial/conventional dual purpose modules. Module 312 may provide conventional clean or degas as necessary for the experiment design.

Any type of chamber or combination of chambers may be implemented and the description herein is merely illustrative of one possible combination and not meant to limit the potential chamber or processes that can be supported to combine combinatorial processing or combinatorial plus conventional processing of a substrate or wafer. In some embodiments, a centralized controller, i.e., computing device 316, may control the processes of the HPC system, including the power supplies and synchronization of the duty cycles described in more detail below. Further details of one possible HPC system are described in U.S. application Ser. No. 11/672,478 filed Feb. 7, 2007, now U.S. Pat. No. 7,867,904 and claiming priority to U.S. Provisional Application No. 60/832,248 filed on Jul. 19, 2006, and U.S. application Ser. No. 11/672,473, filed Feb. 7, 2007 and claiming priority to U.S. Provisional Application No. 60/832,248 filed on Jul. 19, 2006, which are all herein incorporated by reference. With HPC system, a plurality of methods may be employed to deposit material upon a substrate employing combinatorial processes.

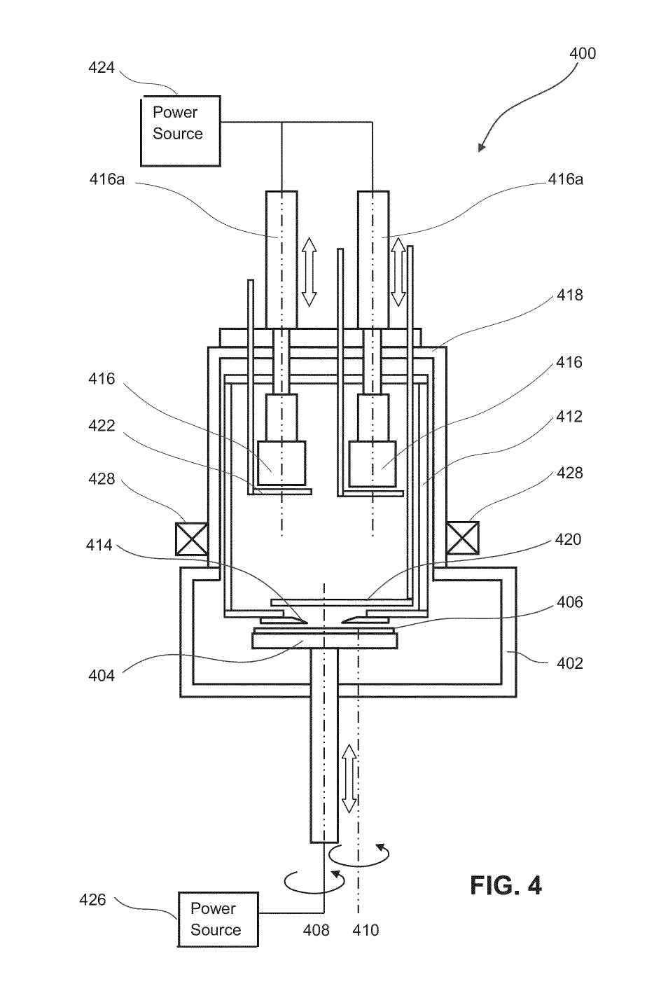

FIG. 4 is a simplified schematic diagram illustrating a sputter chamber configured to perform combinatorial processing and full substrate processing in accordance with some embodiments of the invention. Processing chamber, 400, includes a bottom chamber portion, 402, disposed under top chamber portion, 418. Within bottom portion, 402, substrate support, 404, is configured to hold a substrate, 406, disposed thereon and can be any known substrate support, including but not limited to a vacuum chuck, electrostatic chuck or other known mechanisms. Substrate support, 404, is capable of both rotating around its own central axis, 408 (referred to as “rotation” axis), and rotating around an exterior axis, 410, (referred to as “revolution” axis). Such dual rotary substrate support is central to combinatorial processing using site-isolated mechanisms. Other substrate supports, such as an XY table, can also be used for site-isolated deposition. In addition, substrate support, 404, may move in a vertical direction. It should be appreciated that the rotation and movement in the vertical direction may be achieved through known drive mechanisms which include magnetic drives, linear drives, worm screws, lead screws, a differentially pumped rotary feed through drive, etc. Power source, 426, provides a bias power to substrate support, 404, and substrate, 406, and produces a negative bias voltage on substrate, 406. In some embodiments power source, 426, provides a radio frequency (RF) power sufficient to take advantage of the high metal ionization to improve step coverage of vias and trenches of patterned wafers. In some embodiments, the RF power supplied by power source, 426, is pulsed and synchronized with the pulsed power from power source, 424.

Substrate, 406, may be a conventional round 200 mm, 300 mm, or any other larger or smaller substrate/wafer size. In some embodiments, substrate, 406, may be a square, rectangular, or other shaped substrate. One skilled in the art will appreciate that substrate, 406, may be a blanket substrate, a coupon (e.g., partial wafer), or even a patterned substrate having predefined regions. In some embodiments, substrate, 406, may have regions defined through the processing described herein. The term region is used herein to refer to a localized area on a substrate which is, was, or is intended to be used for processing or formation of a selected material. The region can include one region and/or a series of regular or periodic regions predefined on the substrate. The region may have any convenient shape, e.g., circular, rectangular, elliptical, wedge-shaped, etc. In the semiconductor field a region may be, for example, a test structure, single die, multiple dies, portion of a die, other defined portion of substrate, or an undefined area of a substrate, e.g., blanket substrate which is defined through the processing.

Top chamber portion, 418, of chamber, 400, in FIG. 4 includes process kit shield, 412, which defines a confinement region over a radial portion of substrate, 406. Process kit shield, 412, is a sleeve having a base (optionally integrated with the shield) and an optional top within chamber, 400, that may be used to confine a plasma generated therein. The generated plasma will dislodge atoms from a target and the sputtered atoms will deposit on an exposed surface of substrate, 406, to combinatorial process regions of the substrate in some embodiments. In another embodiment, full wafer processing can be achieved by optimizing gun tilt angle and target-to-substrate spacing, and by using multiple process guns, 416. Process kit shield, 412, is capable of being moved in and out of chamber, 400, (i.e., the process kit shield is a replaceable insert). In another embodiment, process kit shield, 412, remains in the chamber for both the full substrate and combinatorial processing. Process kit shield, 412, includes an optional top portion, sidewalls and a base. In some embodiments, process kit shield, 412, is configured in a cylindrical shape, however, the process kit shield may be any suitable shape and is not limited to a cylindrical shape.

The base of process kit shield, 412, includes an aperture, 414, through which a surface of substrate, 406, is exposed for deposition or some other suitable semiconductor processing operations. Aperture shutter, 420, which is moveably disposed over the base of process kit shield, 412. Aperture shutter, 420, may slide across a bottom surface of the base of process kit shield, 412, in order to cover or expose aperture, 414, in some embodiments. In another embodiment, aperture shutter, 420, is controlled through an arm extension which moves the aperture shutter to expose or cover aperture, 414. It should be noted that although a single aperture is illustrated, multiple apertures may be included. Each aperture may be associated with a dedicated aperture shutter or an aperture shutter can be configured to cover more than one aperture simultaneously or separately. Alternatively, aperture, 414, may be a larger opening and aperture shutter, 420, may extend with that opening to either completely cover the aperture or place one or more fixed apertures within that opening for processing the defined regions. The dual rotary substrate support, 404, is central to the site-isolated mechanism, and allows any location of the substrate or wafer to be placed under the aperture, 414. Hence, the site-isolated deposition is possible at any location on the wafer/substrate.

A gun shutter, 422, may be included. Gun shutter, 422, functions to seal off a deposition gun when the deposition gun may not be used for the processing in some embodiments. For example, two process guns, 416, are illustrated in FIG. 4. Process guns, 416, are moveable in a vertical direction so that one or both of the guns may be lifted from the slots of the shield. While two process guns are illustrated, any number of process guns may be included, e.g., one, three, four or more process guns may be included. Where more than one process gun is included, the plurality of process guns may be referred to as a cluster of process guns. Gun shutter, 422, can be transitioned to cover and isolate the lifted process guns from the processing area defined within process kit shield, 412. In this manner, the process guns are isolated from certain processes when desired. It should be appreciated that gun shutter, 422, may be integrated with the top of the process kit shield, 412, to cover the opening as the process gun is lifted or individual gun shutter, 422, can be used for each target. In some embodiments, process guns, 416, are oriented or angled so that a normal reference line extending from a planar surface of the target of the process gun is directed toward an outer periphery of the substrate in order to achieve good uniformity for full substrate deposition film. The target/gun tilt angle depends on the target size, target-to-substrate spacing, target material, process power/pressure, etc.

Top chamber portion, 418, of chamber, 400, of FIG. 4 includes sidewalls and a top plate which house process kit shield, 412. Arm extensions, 416a, which are fixed to process guns, 416, may be attached to a suitable drive, (i.e., lead screw, worm gear, etc.), configured to vertically move process guns, 416, toward or away from a top plate of top chamber portion, 418. Arm extensions, 416a, may be pivotally affixed to process guns, 416, to enable the process guns to tilt relative to a vertical axis. In some embodiments, process guns, 416, tilt toward aperture, 414, when performing combinatorial processing and tilt toward a periphery of the substrate being processed when performing full substrate processing. It should be appreciated that process guns, 416, may tilt away from aperture, 414, when performing combinatorial processing in another embodiment. In yet another embodiment, arm extensions, 416a, are attached to a bellows that allows for the vertical movement and tilting of process guns, 416. Arm extensions, 416a, enable movement with four degrees of freedom in some embodiments. Where process kit shield, 412, is utilized, the aperture openings are configured to accommodate the tilting of the process guns. The amount of tilting of the process guns may be dependent on the process being performed in some embodiments.

Power source, 424, provides power for sputter guns, 416, whereas power source, 426, provides RF bias power to an electrostatic chuck. As mentioned above, the output of power source, 426, is synchronized with the output of power source, 424. It should be appreciated that power source, 424, may output a direct current (DC) power supply or a radio frequency (RF) power supply. In another embodiment the DC power is pulsed and the duty cycle is less than 30% on-time at maximum power in order to achieve a peak power of 10-15 kilowatts. Thus, the peak power for high metal ionization and high density plasma is achieved at a relatively low average power which will not cause any target overheating/cracking issues. It should be appreciated that the duty cycle and peak power levels are exemplary and not meant to be limiting as other ranges are possible and may be dependent on the material and/or process being performed.

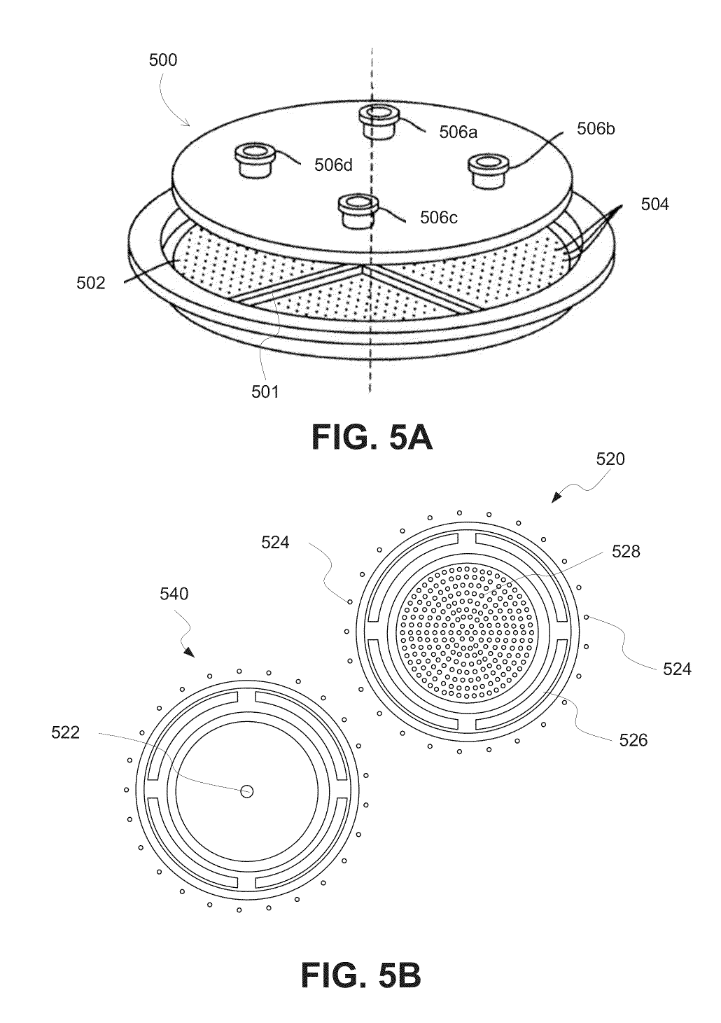

FIG. 5A illustrates an example of a large area ALD or CVD showerhead, 500, used for combinatorial processing. Details of this type of showerhead and its use may be found in U.S. patent application Ser. No. 12/013,729 entitled “Vapor Based Combinatorial Processing” filed on Jan. 14, 2008 and claiming priority to Provisional Application No. 60/970,199 filed on Sep. 5, 2001, U.S. patent application Ser. No. 12/013,759 entitled “Vapor Based Combinatorial Processing” filed on Jan. 14, 2008 and claiming priority to Provisional Application No. 60/970,199 filed on Sep. 5, 2001, and U.S. patent application Ser. No. 12/205,578 entitled “Vapor Based Combinatorial Processing” filed on Sep. 5, 2008 which is a Continuation Application of the U.S. patent application Ser. No. 12/013,729 and claiming priority to Provisional Application No. 60/970,199 filed on Sep. 5, 2001, all of which are herein incorporated by reference.

The large area ALD or CVD showerhead, 500, illustrated in FIG. 5A comprises four regions, 502, used to deposit materials on a substrate. As an example, in the case of a round substrate, four different materials and/or process conditions could be used to deposit materials in each of the four quadrants of the substrate (not shown). Precursor gases, reactant gases, purge gases, etc. are introduced into each of the four regions of the showerhead through gas inlet conduits 506a-506b. For simplicity, the four regions, 502, of showerhead, 500, have been illustrated as being a single chamber. Those skilled in the art will understand that each region, 502, of showerhead, 500, may be designed to have two or more isolated gas distribution systems so that multiple reactive gases may be kept separated until they react at the substrate surface. Also for simplicity, on a single gas inlet conduit, 506a-506d, is illustrated for each of the four regions. Those skilled in the art will understand that each region, 502, of showerhead, 500, may have multiple gas inlet conduits. The gases exit each region, 502, of showerhead, 500, through holes, 504, in the bottom of the showerhead. The gases then travel to the substrate surface and react at the surface to deposit a material, etch an existing material on the surface, clean contaminants found on the surface, react with the surface to modify the surface in some way, etc. The showerhead illustrated in FIG. 5A is operable to be used with any of a CVD, PECVD, ALD, or PEALD technology.

As discussed previously, showerhead, 500, in FIG. 5A results in a deposition (or other process type) on a relatively large region of the substrate. In this example, a quadrant of the substrate. To address the limitations of the combinatorial showerhead illustrated in FIG. 5A, small spot showerheads have been designed as illustrated in FIG. 5B. FIG. 5B illustrates a bottom view of two examples of a small spot showerhead apparatus in accordance with some embodiments of the present invention. Details of the small spot showerhead and methods of its use may be found in co-owned U.S. patent application Ser. No. 13/302,097, filed on Nov. 22, 2011 and co-owned U.S. patent application Ser. No. 13/302,730, filed on Nov. 22, 2011, each of which are herein incorporated by reference for all purposes. The small spot showerhead configuration, 540, illustrated in FIG. 5B comprises a single gas distribution port, 522, in the center of the showerhead for delivering reactive gases to the surface of the substrate. The small size of the small spot showerhead and the behavior of the technologies envisioned to use this showerhead ensure that the uniformity of the process on the substrate is adequate using the single gas distribution port. However, the small spot showerhead configuration, 520, illustrated in FIG. 5B comprises a plurality of gas distribution ports, 528, for delivering reactive gases to the surface of the substrate. This configuration can be used to improve the uniformity of the process on the substrate if required.

Each small spot showerhead is surrounded by a plurality of purge holes, 524. The purge holes introduce inert purge gases (i.e. Ar, N₂, etc.) around the periphery of each small spot showerhead to insure that the regions under each showerhead can be processed in a site isolated manner. The gases, both the reactive gases and the purge gases, are exhausted from the process chamber through exhaust channels, 526, that surround each of the showerheads. The combination of the purge holes, 524, and the exhaust channels, 526, ensure that each region under each showerhead can be processed in a site isolated manner. The diameter of the small spot showerhead (i.e. the diameter of the purge ring) can vary between about 40 mm and about 100 mm. Advantageously, the diameter of the small spot showerhead is about 65 mm.

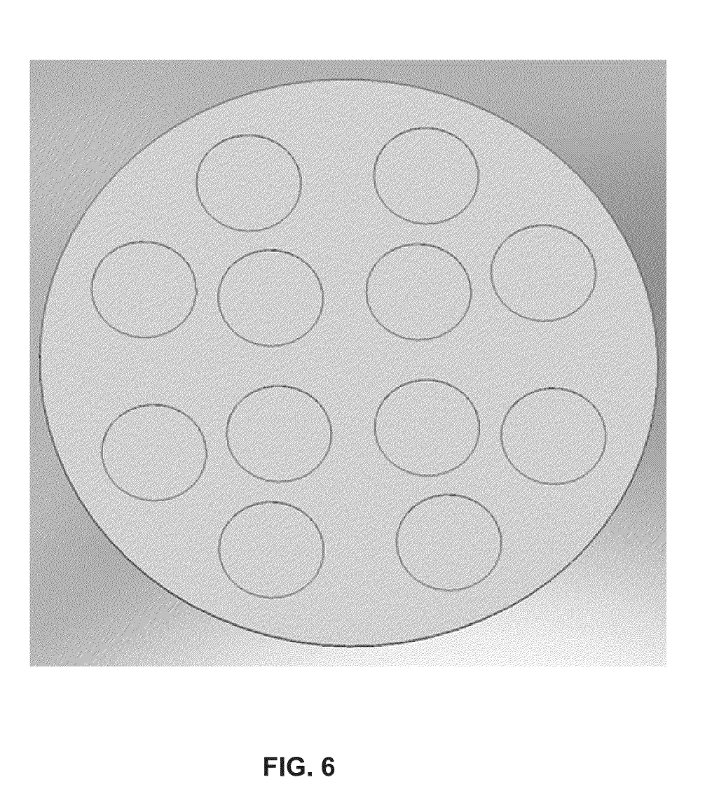

Using a plurality of small spot showerheads as illustrated in FIG. 5B allows a substrate to be processed in a combinatorial manner wherein different parameters can be varied as discussed above. Examples of the parameters comprise process material composition, process material amounts, reactant species, processing temperatures, processing times, processing pressures, processing flow rates, processing powers, processing reagent compositions, the rates at which the reactions are quenched, atmospheres in which the processes are conducted, an order in which materials are deposited, etc. FIG. 6 illustrates one example of a pattern of site isolated regions that can be processed using a small spot showerhead apparatus in accordance with some embodiments of the present invention. In FIG. 6, the substrate is still generally divided into four quadrants and within each quadrant, three site isolated regions can be processed using small spot showerheads as illustrated in FIG. 5B, yielding twelve site isolated regions on the substrate. Therefore, in this example, twelve independent experiments could be performed on a single substrate.

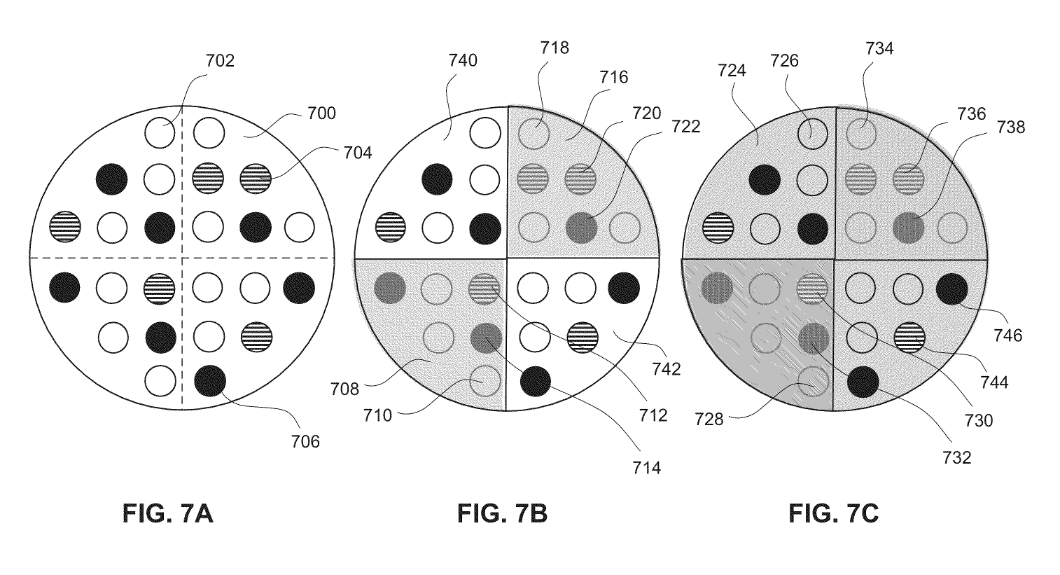

FIGS. 7A-7C illustrate a top view of site-isolated regions and film stacks formed by a PVD-ALD-CVD sequence in accordance with some embodiments. FIG. 7A illustrates a substrate, 700, including a plurality of site-isolated regions (SIRs), 702. The 24 SIRs are evenly distributed into four quadrants of the substrate. Dashed lines have been added to aid in the visualization of the quadrants. Although 24 SIRs are illustrated in FIG. 7A, those skilled in the art will understand that any number of site-isolated regions may exist on the substrate. In FIG. 7A, a first number of the SIRs have been processed using a PVD technique to deposit a material, as illustrated by hatched SIRs 704. In FIG. 7A, a second number of the SIRs have been processed using a PVD technique to deposit a material, as illustrated by solid SIRs 706. Note that some of the SIRs in each quadrant of the substrate do not have material deposited on them in FIG. 7A (i.e. open SIRs 702). The materials in SIRs 704 and 706 may be different because of at least one of material composition, surface pretreatment, thickness, uniformity, or deposition conditions. Examples of deposition conditions that may be varied include power, pressure, sputtering gas composition, substrate temperature, substrate bias, target to substrate distance, or power supply frequency. As discussed previously, the thickness of the materials deposited in SIRs 704 and 706 is greater than about 60 A. This thickness ensures that the work function derived from measurements made in these regions is dominated by the materials deposited in this step and will not be affected by materials deposited in later processing steps.

In some embodiments, the substrate may be transferred to an ALD chamber without be exposed to the ambient using a system as described in FIG. 3. In some embodiments, the substrate may be transferred to a stand-alone ALD chamber. In FIG. 7B, a first quadrant of the substrate has been processed using an ALD technique to deposit a material, as illustrated by hatched quadrant 708. In FIG. 7B, a second quadrant of the substrate has been processed using an ALD technique to deposit a material, as illustrated by hatched quadrant 716. Note that two of the quadrants of the substrate do not have material deposited on them in FIG. 7B (i.e. open quadrants 740 and 742). The materials in quadrants 708 and 716 may be different because of at least one of material composition, surface pretreatment, thickness, uniformity, or deposition conditions. Examples of deposition conditions that may be varied include pressure, precursor composition, reactant composition, substrate temperature, precursor pulse time, reactant pulse time, precursor flow rate, reactant flow rate, or precursor-reactant pulse sequences. In FIG. 7B, some SIRs have only the first ALD material deposited in them (i.e. SIRs 710). In FIG. 7B, some SIRs have the first ALD material and the first PVD material deposited in them (i.e. SIRs 712). In FIG. 7B, some SIRs have the first ALD material and the second PVD material deposited in them (i.e. SIRs 714). In FIG. 7B, some SIRs have only the second ALD material deposited in them (i.e. SIRs 718). In FIG. 7B, some SIRs have the second ALD material and the first PVD material deposited in them (i.e. SIRs 720). In FIG. 7B, some SIRs have the second ALD material and the second PVD material deposited in them (i.e. SIRs 722). As discussed previously, the thickness of the materials deposited in SIRs 710 and 718 is greater than about 60 A. This thickness ensures that the work function derived from measurements made in these regions is dominated by the materials deposited in this step and will not be affected by materials deposited in later processing steps.

In some embodiments, the substrate may be transferred to a CVD chamber without be exposed to the ambient using a system as described in FIG. 3. In some embodiments, the substrate may be transferred to a stand-alone CVD chamber. In FIG. 7C, the entire substrate has been processed using a CVD technique to deposit a material, as illustrated by shading 724. In FIG. 7C, some SIRs have only the CVD material deposited in them (i.e. SIRs 726). In FIG. 7C, some SIRs have the CVD material and the first PVD material deposited in them (i.e. SIRs 744). In FIG. 7C, some SIRs have the CVD material and the second PVD material deposited in them (i.e. SIRs 746). In FIG. 7C, some SIRs have the CVD material and the first ALD material deposited in them (i.e. SIRs 728). In FIG. 7C, some SIRs have the CVD material and the second ALD material deposited in them (i.e. SIRs 734). In FIG. 7C, some SIRs have the CVD material, the first ALD material, and the first PVD material deposited in them (i.e. SIRs 730). In FIG. 7C, some SIRs have the CVD material, the first ALD material, and the second PVD material deposited in them (i.e. SIRs 732). In FIG. 7C, some SIRs have the CVD material, the second ALD material, and the first PVD material deposited in them (i.e. SIRs 736). In FIG. 7C, some SIRs have the CVD material, the second ALD material, and the second PVD material deposited in them (i.e. SIRs 738). As discussed previously, the thickness of the materials deposited in SIRs 726 is greater than about 60 A. This thickness ensures that the work function derived from measurements made in these regions is dominated by the materials deposited in this step and will not be affected by materials deposited in later processing steps.

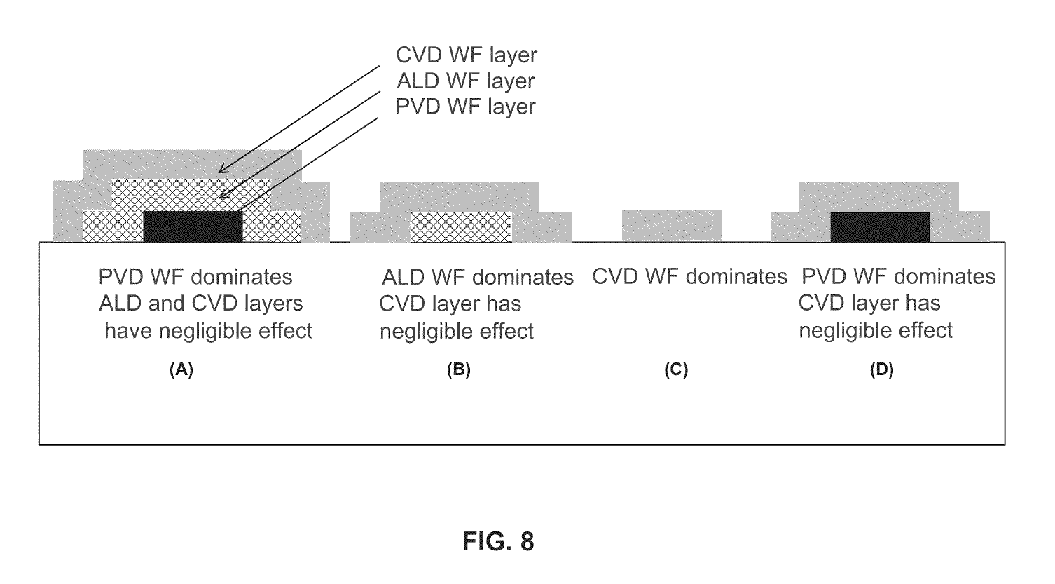

FIG. 8 illustrates an exemplary deposition sequence for forming multilayer film stacks according to some embodiments. Film stacks illustrated in (A) correspond to SIRs that received depositions from all three deposition techniques—PVD—ALD—CVD (e.g. SIRs 730, 732, 736, 738). However, as discussed previously, the work function measurements in these SIRs are dominated by the materials deposited by PVD. The overlying ALD and CVD materials have a negligible contribution to the work function. Film stacks illustrated in (B) correspond to SIRs that received depositions from two deposition techniques—ALD—CVD (e.g. SIRs 728, 734). However, as discussed previously, the work function measurements in these SIRs are dominated by the materials deposited by ALD. The overlying CVD materials have a negligible contribution to the work function. Film stacks illustrated in (C) correspond to SIRs that received depositions from only one deposition technique—CVD (e.g. SIRs 726). The work function measurements in these SIRs are dominated by the materials deposited by CVD. Film stacks illustrated in (D) correspond to SIRs that received depositions from two deposition techniques—PVD—CVD (e.g. SIRs 744, 746). However, as discussed previously, the work function measurements in these SIRs are dominated by the materials deposited by PVD. The overlying CVD materials have a negligible contribution to the work function.

Each of the capacitors in the various SIRs would then be tested to determine the optimum material and/or processing conditions. Typical tests may comprise measuring capacitance as a function of applied voltage (i.e. C-V curve), measuring current as a function of applied voltage (i.e. I-V curve), measuring the k value of the dielectric material, measure the equivalent oxide thickness (EOT) of the dielectric material, measuring the concentration and energy levels of traps or interface states, measuring the concentration and mobility of charge carriers, etc.

FIGS. 7A-7C use a simple capacitor stack to illustrate various deposition sequences for forming multilayer film stacks. These methods may be applied to specific devices that are of technological importance.

In a first example, the methods described above can be applied to the development of metal-oxide-semiconductor (MOS) capacitor stacks. In their simplest configuration, MOS capacitor stacks comprise a bottom electrode (BEC) material, a dielectric material, and a top electrode (TEC) material. As discussed previously, the WF can be obtained from C-V measurements of the MOS capacitor. In some embodiments, the BEC and the dielectric material are formed in each of the SIRs illustrated in FIGS. 7A-7C prior to the PVD deposition. In some embodiments, many capacitors with different areas are formed within each SIR so that many data may be obtained and indications of how the material properties and the device performance scale with capacitor area can be obtained. In some embodiments, the substrate is processed through sequential deposition techniques including PVD, ALD, and CVD as illustrated in FIGS. 7A-7C wherein the material and/or the process conditions are varied in a combinatorial manner between the various SIRs on the substrate. In some embodiments, at least two of the deposition techniques are performed without removing the substrate from a cluster processing system as illustrated in FIG. 3. In some embodiments, all of the deposition techniques are performed in stand-alone processing systems.

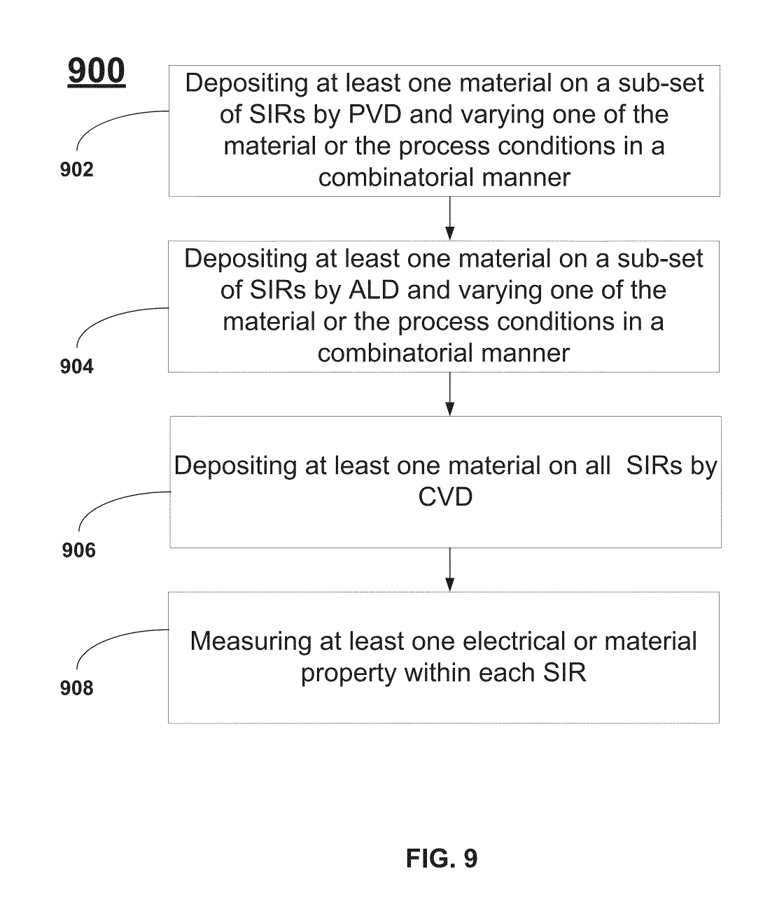

FIG. 9 illustrates a flow chart describing a method for fabricating a capacitor stack in accordance with some embodiments. In step 902, at least one material is deposited on a sub-set of SIRs by PVD as discussed previously with respect to FIG. 7A. At least one of the material or the process conditions are varied in a combinatorial manner as discussed previously. In the next step, 904, at least one material is deposited on a sub-set of SIRs by ALD as discussed previously with respect to FIG. 7B. At least one of the material or the process conditions are varied in a combinatorial manner as discussed previously. In the next step, 906, a material is deposited on the entire substrate by CVD as discussed previously with respect to FIG. 7C. In the next step, 908, each capacitor within each of the SIRs is evaluated wherein the evaluation involves the measurement of at least one electrical or material property. In some embodiments, the property is the WF of the top electrode.

Although the foregoing examples have been described in some detail for purposes of clarity of understanding, the invention is not limited to the details provided. There are many alternative ways of implementing the invention. The disclosed examples are illustrative and not restrictive.

What is claimed is:

1. A method for forming a film stack comprising:
defining a plurality of site-isolated regions (SIRs) on a substrates;
forming a first material on a first sub-set of the SIRs using a PVD technique, wherein at least one of a material or process condition is varied across the first sub-set of SIRs in a combinatorial manner;
forming a second material on a second sub-set of the SIRs using an ALD technique, wherein at least one of a material or process condition is varied across the second sub-set of SIRs in a combinatorial manner;
forming a third material on the entire substrate using a CVD technique; and
measuring at least one property of at least one device formed within each SIR,
wherein some of the SIRs of the second sub-set of SIRs are included in the first sub-set of SIRs, some of the SIRs of the first sub-set of SIRs are not included in the second sub-set of SIRs and some of the SIRs of the second sub-set of SIRs are not included in the first sub-set of SIRs.

2. The method of claim 1 wherein a composition of the first material is varied between at least two of the first isolated regions.

3. The method of claim 1 wherein a set of process conditions of the first material is varied between at least two of the first isolated regions.

4. The method of claim 1 wherein the first material is a conductive material operable as an electrode of a device.

5. The method of claim 1 wherein the second material is formed using a large area combinatorial showerhead.

6. The method of claim 1 wherein a composition of the second material is varied between at least two of the first isolated regions.

7. The method of claim 1 wherein a set of process conditions of the second material is varied between at least two of the first isolated regions.

8. The method of claim 1 wherein the second material is a conductive material operable as an electrode of a device.

9. The method of claim 1 wherein the third material is a conductive material operable as an electrode of a device.

10. The method of claim 1 wherein the second sub-set of SIRs includes some of the first sub-set of SIRs.

11. The method of claim 1 wherein after the forming of the third material, a film stack formed from the deposition of the first material, the deposition of the second material, and the deposition of the third material is on some of the plurality of SIRs.

12. The method of claim 11 wherein after the forming of the third material, a film stack formed from the deposition of the first material, the deposition of the second material, and not the deposition of the third material is on some of the plurality of SIRs.

13. The method of claim 12 wherein after the forming of the third material, a film stack formed from the deposition of the first material, the deposition of the third material, and not the deposition of the second material is on some of the plurality of SIRs.

14. The method of claim 13 wherein after the forming of the third material, a film stack formed from the deposition of the second material, the deposition of the third material, and not the deposition of the first material is on some of the plurality of SIRs.

15. The method of claim 14 wherein after the forming of the third material, a film stack formed from the deposition of the third material and not the deposition of the first material and the second material is on some of the plurality of SIRs.

16. The method of claim 1 wherein the measuring comprises one of measuring capacitance as a function of applied voltage (i.e. C-V curve), measuring current as a function of applied voltage (i.e. I-V curve), measuring the k value of the dielectric material, measure the equivalent oxide thickness (EOT) of the dielectric material, measuring the concentration and energy levels of traps or interface states, and the measuring the concentration and mobility of charge carriers.

17. The method of claim 1 wherein the property is at least one of an electrical property or a material property.

18. The method of claim 1 wherein the property is the work function of one of the first material, the second material, or the third material.

19. A method for forming a film stack comprising:
defining a plurality of site-isolated regions (SIRs) on a substrate;
forming a first material on a first sub-set of the SIRs using a PVD technique, wherein at least one of a material or process condition is varied across the first sub-set of SIRs in a combinatorial manner;
forming a second material on a second sub-set of the SIRs using an ALD technique, wherein at least one of a material or process condition is varied across the second sub-set of SIRs in a combinatorial manner;
forming a third material on the entire substrate using a CVD technique; and
measuring at least one property of at least one device formed within each SIR,
wherein at least one of the first material and the second material is not formed on some of the plurality of SIRs.

20. The method of claim 1 wherein some of the SIRs of the second sub-set of SIRs are included in the first sub-set of SIRs, some of the SIRs of the first sub-set of SIRs are not included in the second sub-set of SIRs and some of the SIRs of the second sub-set of SIRs are not included in the first sub-set of SIRs.
